(19) United States
(12) Patent Application Publication
(10) Pub. No.: US 2006/0008970 A1
(43) Pub. Date: Jan. 12, 2006

(54) OPTIMIZED PLATING PROCESS FOR MULTILAYER PRINTED CIRCUIT BOARDS HAVING EDGE CONNECTORS

(75) Inventors: Stefano Oggioni, Milano (IT); Giorgio Viero, Stezzano (BG) (IT)

Correspondence Address: IBM MICROELECTRONICS;INTELLECTUAL PROPERTY LAW, 1000 RIVER STREET, 972 E, ESSEX JUNCTION, VT, 05452, US

(73) Assignee: INTERNATIONAL BUSINESS MACHINES CORPORATION, Armonk, NY (US)

(21) Appl. No.: 11/160,780

(22) Filed: Jul. 8, 2005

(30) Foreign Application Priority Data
Jul. 8, 2004 (EP) EP04103253.3

(51) Int. Cl. H01L 21/8238

(52) U.S. Cl. 438/221

(57) ABSTRACT

A process for manufacturing printed wire boards with hard plated sliding contact tabs and soft plated wire bond pads. Sliding contact tabs are covered by a protective coating after being hard plated thus allowing the soft plating of wire bond pads without damaging the hard plated sliding contact tabs. In a preferred embodiment, the hard plating includes the step of electroplating nickel on the sliding contact tabs, followed by electroplating an alloy of gold and cobalt, using standard electroplating process. An electro-less soft plating process includes the steps of plating a nickel layer on the wire bond pads and then a gold layer after having “flash-etched” the copper seeding.

### FIELD OF THE INVENTION

The present invention relates generally to the manufacturing process of printed circuit boards and more specifically to an optimized process for multilayer printed circuit boards having edge connectors.

### BACKGROUND OF THE INVENTION

A conventional printed circuit device, such as a Printed Circuit Board (PCB), also known as Printed Wire Board (PWB), includes pads for attachment of surface mounted devices and connection to other circuit elements. The surfaces are masked and the exposed pads prepared with appropriate coatings for the attachment process. Where multiple attachment techniques are used, the preparatory coatings of the pads must be adapted to the particular
connective process employed.

Several types of attachments require pad coatings with different physical characteristics. The application described in this document, as an example of a device employing multiple attachment techniques, is a PCB that carries wirebond chips and mechanical connectors for plugging such PCB into an electronic device such as another PCB or a backplane. A typical example of such board is found in any Personal Computer Memory Card International Association
(PCMCIA) cards, also referred to as PC cards. FIG. 1 illustrates an example of a PCB 100 with Surface Mount Components (SMC) and wirebond chips, generically referred to as 105 and 110, respectively. As shown, electrical connections between electronic components 105/110 and PCB 100 are
accomplished using pads 115. PCB 100 also includes a second pad, also referred to as sliding contact tabs, sliding pads, or fingers, and generically
noted 120, that are adapted for plugging PCB 100 into a connector of another PCB or backplane (not represented for sake of clarity). As mentioned above, the electrical connection established with the two kinds of pads differs since in
the first case the connection is done by soldering while in the second case, the connection is established by a mechanical pressure. As a consequence, the material used for manufacturing these two kinds of pads must be adapted to
provide a reliable connection.

U.S. Pat. No. 5,910,644 discloses a printed circuit connector terminal pad coating technique which functions as a single universal pad surface which supports multiple electrical connection practices including wirebonding, soldering, and wear resistant, pad on pad mechanical connection. The tri-plate surface treatment includes an initial diffusion resistant coating of nickel; an intermediate layer of hard, wear resistant noble or semi-noble metal that provides pad on pad connector reliability and affords metallurgically stable solder joints and wirebond interface; and a final coating of soft gold. The intermediate layer may be pure palladium having a nominal thickness of 0.035 inches or a layer of gold, hardened by cobalt, nickel, iron or a combination of these dopants to effect a hardness of 200 to 250 (Knoop scale). The use of a common surface treatment for the multiple attachment processes is implemented
with a single masking step, rather than a sequence of selective masking, plating and stripping operations. In the printed circuit environment, the masking is provided by the final covering that encloses, seals, and electrically insulates the conductors in a circuit board application or in the instance of a flexcable, the adhesive coated flexible coverlay that covers and seals the copper conductor elements while exposing the conductor terminal pads. However, even if it is possible to build “universal” pads that support multiple electrical connection practices, the pads of some applications have to deal with constraints that are outside the specifications of such “universal” pads.

A PCB designed for high frequency electronic components must comply with the plug-in specifications defined by the Secure Digital Memory Card Format (an international standard for portable devices used on mobile appliances), which requires the use of different pads for mechanical connection and soldering. For example, it would be advantageous to use soft gold for soldering pads, providing very good electrical connection and hard gold for pads dedicated to mechanical contacts so as to ensure a reliable contact through thousands of plug and unplug cycles in and out of systems (SD Memory Card Specifications, Version 1.0, requires 10K mating cycles for durability). It is well known that soft gold and hard gold plating processes are not compatible in materials and processes, either in the sequence of the operations i.e., which of the two plating processes has to come last, or to the process steps that need to be performed on the two different plated portions later in the product assembly phases, due in particular to the contamination residues left from the other plating process. Traditional baths from which to plate soft gold as well as hard gold contain the cyanide complex (Au[CN]2) as the source of the gold, which liberates free cyanide ions during the plating. However, the free cyanide is not only toxic but also attacks photo-resists used to delineate the fine pitch circuit features and wire bonding pads.

For these reasons, a major trend in the industry is to use non-cyanide with
sulfite baths to plate soft gold, whereas hard gold can be plated only from cyanide baths at present. Plating requirements are also different based on the utilization of the plated features. For wirebonded pads, a base of nickel plate (electroplated or electro-less) with a thickness of 4 um or more is required in combination with a gold plated layer that can be different in thickness depending on the type of host wire bond. Ultrasonic bonding with aluminum wire requires only a thin gold layer (less than 0.1 um), the bond is between the aluminum wire and the under-layer of nickel. This method of gold plating, also known as gold flash, uses an auto-catalytic chemical reaction to create a gold layer on top of the plated nickel layer, which causes the last layer of nickel atoms to be replaced by atoms of gold. This is a self-limited reaction that does not allow thicker gold layers to grow and it is porous in nature. For thermo-sonic bonding with gold wire, the noble layer has to be thicker than 0.5 um to obtain good and reliable wire-bonding in production. For soft gold layers, a base of nickel (4.0 um thickness or greater) and a flash of gold are required prior to plating the thicker soft gold. The hard gold layer for the connector tabs requires a minimum nickel layer having a thickness greater than 2.54 um, however, the gold layer has to be minimum of 0.762 um. Nominal designs specifications require 1.0 um gold thickness with a maximum tolerance of ±15%. Soft gold being deposited with an electro-less process can be applied without affecting the functional design of the circuitry.

For the hard electrolytic process, for example in the Gold Finger Plating (usually carried out for Peripheral Component Interconnect (PCI) cards), the fabricator generally runs trace/bus bars off the PCB edge to a common bus to provide the current during the (post etch) plating process. At the edge trim (routing) stage, the trace bus/bar gets cut away along the gold plated finger edge. This is only possible if the tabs are placed along one of the edges of the substrate, which requires beveling after routing to remove metal strips left over from the routing operation. The beveling step can be performed on large features (connectors' tabs) but is very difficult on fine pitch features (bonding pads at i.e. 150 um pitch).

While edge connectors have been widely used in personal computers and information technology applications generally, a newly developed family of PCBs is pervasively expanding in these sectors as well as in electronic consumer
products. This new PCB technology, generically referred to as build up (BU) technology, uses added layers to a standard rigid PCB core. The main advantage of this new family of products is the utilization of pure resin layers, in place of reinforced (resin impregnated) woven glass cloths, using photolithographic processes. Such implementations allow the definition of much smaller circuit details (i.e. vias, lines) than with standard methodology. The pure resin dielectric layer also allows the processing of drilling by laser achieving very small hole diameters in the layer to layer interconnections. The materials now used as dielectrics have more chemical and physical characteristics like “plastic” than of the traditional composite materials, the latter having a predominant behavior driven by the glass presence, even when using the same resin complex. BU substrates enable greater physical scaling, but the added dielectric layers are very thin, usually in the range from 25 to 35 um. Due to the aforementioned reasons there are problems with implementing edge connectors on build-up substrates. For example, one of the major concerns for edge connectors is the temperature of glass transition (Tg) of the specific resin complex. The Tg of a resin is the temperature at which an amorphous polymer (or the amorphous regions in a partially crystalline polymer) changes from a hard and relatively brittle condition to a viscous or rubbery condition. Typical amorphous polymers used in electronics are: FR-4 (epoxy), Polyimide, BT (Bismaleimide Triazine) etc. The Tg of these polymers can range from room temperature to hundreds of degree Celsius based on the resin complex. In materials used for electronic circuits these temperatures are usually in the range between 100° C. and 190° C. with the higher temperature range amorphous polymers being the most expensive. Softening of the base material carrying edge connectors is a medium to long term reliability issue. It becomes more a short term problem where functional temperature ranges are high enough to approach the Tg of the amorphous polymer, or in consumer products where electrical components may see high temperature excursion even when they are not in operation. This temperature increase and a consequent softening of the material may induce a local collapse/yield of the PCB contacting pad structures thus making the sliding pad-to-pad spring-loaded contacts unreliable, so as to affect system performance with intermittent or total failures.

Another potential reliability issue is that the adhesion of copper and consequently of copper traces, over build up layers is much lower than the copper adhesion on PCB cores. Beveling can tear pads away from the laminate on build up layers. Therefore, there is a need for a process flow for making PCB wherein it is possible to implement sliding contact tabs on the top of the PCB core, preferably made of reinforced glass cloth plies that exhibit greater hardness while still maintaining all the benefits offered by sequential build up technologies in terms of wiring density and physical scaling.

### SUMMARY OF THE INVENTION

Thus, it is a broad object of the invention to remedy the shortcomings of the prior art as described above. It is another object of the invention to provide a method for manufacturing Printed Wire Board (PWB) comprising hard gold plated sliding contact tabs and soft gold soldering pads, the method using standard PWB manufacturing steps. It is a further object of the invention to provide a
method for manufacturing Printed Wire Board (PWB) comprising hard gold plated sliding contact tabs, the method using standard PWB manufacturing steps, while providing all the benefits offered by sequential build up technologies. The accomplishment of these and other related objects is achieved by a method for manufacturing Printed Wire Board (PWB) from a core having at least one external conductive layer, said method comprising the steps of,
etching said at least one external conductive layer, to form at least one sliding contact tab;
applying a dielectric material on said at least one external conductive layer;
removing partially said dielectric material from said at least one sliding contact tab;
electroplating said at least one sliding contact tab;
applying a protective coating on said at least one sliding contact tab;
applying colloidal seeding material on said dielectric material;
plating partially said colloidal seeding material using an additive process; and,
removing said protective coating from said at least one sliding contact tab.

Further advantages of the present invention will become apparent to the ones skilled in the art upon examination of the drawings and detailed description. It is intended that any additional advantages be incorporated herein.

### BRIEF DESCRIPTION OF THE DRAWINGS

FIG. 1 depicts an example of a printed circuit board with sliding contact tabs, soldered surface mount components (SMC) and wire bonded chips.

FIG. 2 shows a flow chart describing the method of an optimized plating process according to a first embodiment.

FIGS. 3a to 3k illustrate the main steps in the manufacturing process described in the flow diagram of FIG. 2. Each figure comprises a partial plan view and a partial cross section view, however, the scaling is not the same.

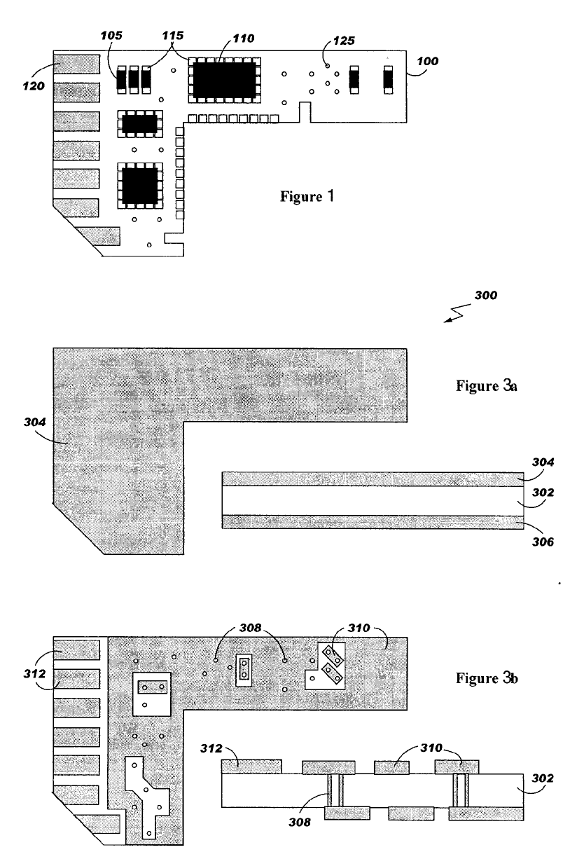

### DETAILED DESCRIPTION OF THE PREFERRED EMBODIMENT

In the following detailed description of embodiments, reference is made to the accompanying drawings which form a part hereof, and in which are shown by way of illustration specific embodiments are described in sufficient detail to enable those skilled in the art to practice the invention, and it to be understood that other embodiments may be utilized and logical, structural, electrical and other changes may be made without departing from the scope of the present invention.

According to the invention there is provided a process for manufacturing printed circuit boards with hard plated sliding contact tabs and soft plated pads, using standard manufacturing steps so as to take advantage of existing manufacturing tools. For sake of illustration, the manufacturing process according to the method of the invention is described in conjunction with reinforced glass core and hard and soft gold plating however, it is to be understood that other materials can be used. For example, the pads used for soldering a surface mount component or for wirebonding can be made of any noble metal such as pure gold or palladium or can be made of an alloy of gold and palladium, palladium recovers by a thin layer of gold, or copper recovers by a thin layer of gold or palladium.

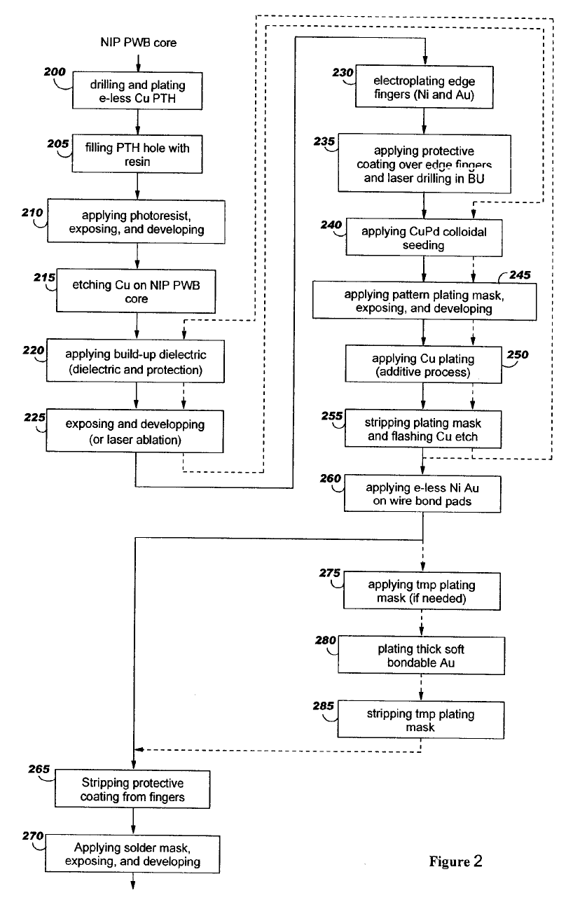

Referring to FIG. 2, an example of the manufacturing process according to the method of the invention is shown. For sake of illustration, the used core is a
reinforced glass No-Internal Planes (NIP) Printed Wire Board (PWB) core. As shown, a first step consists in drilling the core and plating the holes with electrically conductive material so as to create vias, or Plated Through Holes (PTH), in the core (step 200). In a preferred embodiment, the holes are plated with copper using an electro-less process. Then, the holes are filled with resin (step 205) and photoresist material is applied, exposed, and developed (step 210) on both surfaces of the NIP PWB core. Since all the steps of the process are generally applied symmetrically on the top and the bottom of the NIP PWB core, it will not be repeated in the following description that identical steps are performed on each side but it will be indicated if the processes applied on each surface differ. After photoresist material has been developed, the conductive tracks are made (step 215) e.g., Copper is etched off on the surfaces of the core, and a layer of build-up dielectric material is applied on the whole surface of the core (step 220). These steps of masking the core and etching copper are standard steps for making conductive tracks on PCB. The dielectric material applied on the core fulfils two objectives. It is used first for its insulative electrical property, as usual, but also as a protective layer to avoid any damage or partial plating on the conductive tracks when applying the hard gold layer on the sliding contact tabs. To prepare the deposit of hard gold, the applied dielectric material is exposed and developed so as to remove dielectric material on the sliding
contact tabs (step 225). The dielectric material could also be removed using laser ablation. Then, nickel, followed by an alloy of gold and cobalt, is electroplated on the sliding contact tabs (step 230) using standard electroplating process, and a protective coating is applied over the plated sliding contact tabs (step 235). For example, common metal etch-type liquid resist materials are based on derivatives of polysoprene rubber. The liquid resist reacts with a sensitizer (bisazide) upon exposure to actinic (UV) radiation to produce a tough, crosslinked material which is chemically resistant to metal etchants while it has good adhesion to metal surfaces. A large number of photoresist applications for circuit boards also use Dry-film type systems, which are multilayer organic composite systems with a flexible photoresist film between release and cover
sheets. These are laminated (applying heat and pressure) to panels after removing the cover and release sheet. Most of the dry-film negative acting resist (the coating remains in the light-struck areas) are based upon acrylate chemistry. The formulation of these resist films consist of a multifunctional monomer, such as trimethylolpropane triacrylate dissolved in a long chain poly ethyl-methacrylate binder. Additional chemicals are also added to improve performance, including photoinitiator, adhesion promoter, coloring dyes and plasticizers. Polymerization is achieved by exposure to ultraviolet light.

Temporary masks differ in chemistry to standard dielectric materials (i.e. Epoxies) used to add layers to PCB, which makes their selective stripping possible. The vias required for electrically connecting the conductive layers
disposed on each side of the above mentioned dielectric material are built using a standard technique with mechanical drilling in the core-rigid section of the PCB, while the added layers in the build-up portion vias are generally produced by laser drilling. At that point, a seeding layer of colloidal alloy of copper and palladium is applied on the whole surface of the core i.e., dielectric material and protective coating (step 240), on which photoresist material is applied, exposed, and developed to create a pattern plating mask (step 245). Then, an additive copper plating process is used for building the conductive tracks on the applied dielectric material (step 250), where the pattern plating mask has been removed, using the seeding layer of colloidal alloy of copper and palladium, and the pattern plating mask is stripped (step 255). Then the copper seeding is flash-etched.

According to the requirements, it is possible to build several conductive layers on the NIP PWC core structure. To that end, steps 220 to 225 and steps 240 to 255 are repeated for each conductive layers to build, as suggested by dotted arrows. After having built all the conductive layers, the soft gold is applied on the wire bond pads using an electro-less process (step 260). To that end, a standard solution consists in plating a nickel layer on the wire bond pads and then a gold layer. Then, the process varies according to the method of soldering the electronic components on the board. When using Surface Mount Technology (SMT) and/or aluminum wire bond, the protective coating applied over the plated sliding contact tabs is stripped (step 265) and a solder mask is applied on the core surface, exposed, and developed (step 270), to protect the board, as is standard.

When using thermo-sonic wire bond without SMT, it is preferable to plate a thick soft bondable gold on the pads before removing the protective coating applied over the plated sliding contact tabs. To that end, a temporary plating mask is preferably applied on the board so as to plate only the wire bond pads (step 275), a thick soft bondable gold is plated (step 280), and the temporary mask is stripped (step 285).

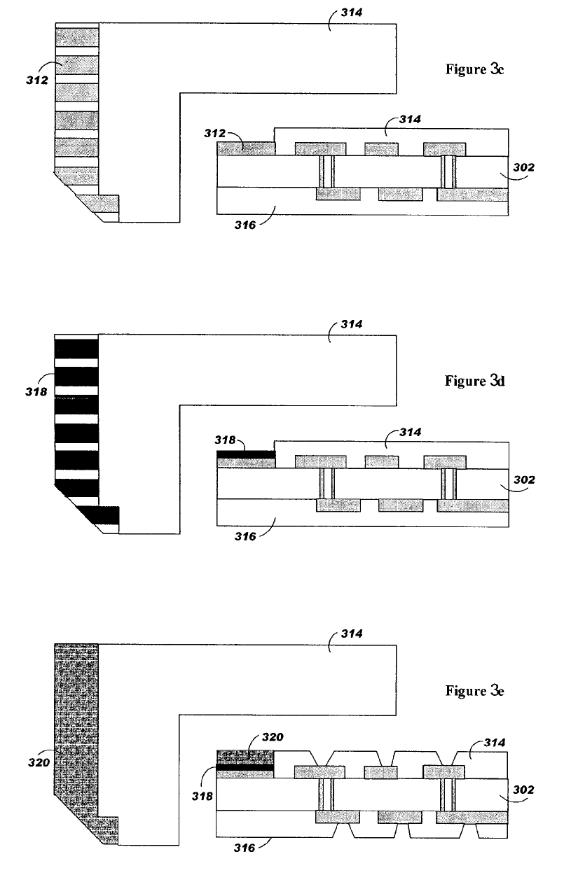

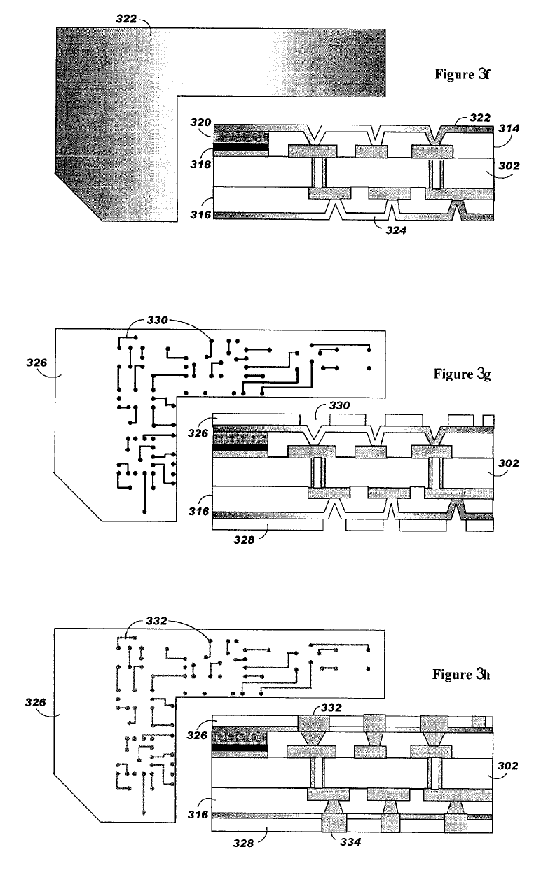

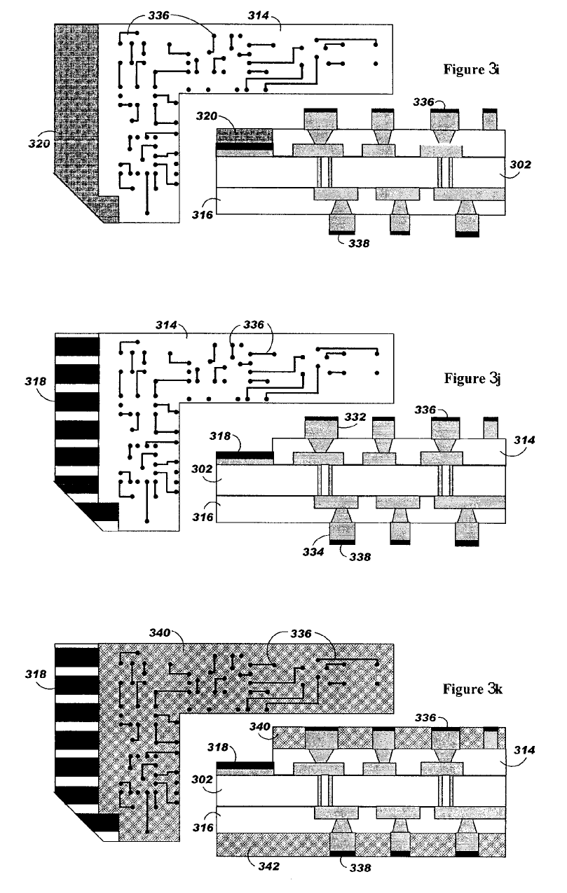

FIG. 3, comprising FIGS. 3a to 3k, illustrates the main steps of the process described above. Each figure comprises a partial plan view and a partial cross section view. For sake of clarity, the partial plan view and the partial cross section view are not using the same scale.

FIG. 3a shows the reinforced glass with no inner conductive layers known as No-Internal Planes (NIP) Printed Wire Board (PWB) core 300 with an internal reinforced woven glass cloth layer 302, an upper copper layer 304 and a bottom copper layer 306. PWB 300 is used as a base to build the required conductive tracks and the sliding contact tabs, as described in the flow diagram of FIG. 2.

FIG. 3b depicts the state of PWB 300 core after having drilled holes 308, plated these holes 308 with electrically conductive material such as copper, filled the holes with resin and formed conductive tracks 310 and sliding contact tabs 312 in the copper planes 304 and/or 306. For sake of illustration the sliding contact tabs are shown only on the 304 layer but they can be on either one side or both. For designing conductive tracks 310 and sliding contact tabs 312 a standard subtractive (pattern definition from a full plane) process is implemented, a photoresist material is applied on the copper layers. This photoresist material is then exposed and developed so as to remove material where conductive material must be removed. Gaps in between copper tracks are etched off on the PWB where photoresist material has been removed. Therefore, at the end of this process, the core comprises electrical connection between its surfaces where conductive tracks are designed, as illustrated. FIG. 3b shows the state of the board after having applied steps 200 to 215 of the flow diagram in FIG. 2.

FIG. 3c illustrates the configuration of PWB 300 when dielectric material layers 314 and 316 have been applied on its surfaces and partially removed to uncover the sliding contact tabs 312 i.e., after having applied steps 220 and 225 of FIG. 2.

FIG. 3d depicts the state of PWB 300 when nickel, followed by an alloy of gold and cobalt (318), has been electroplated on the sliding contact tabs 312. For sake of clarity, the plating bus bar is not shown and the sliding contact tabs plated with hard gold are referred to as 318.

FIG. 3d illustrates the state of PWB 300 after having applied step 230 of FIG. 2.

FIG. 3e shows the state of PWB 300 after hard gold plated sliding contact tabs 318 have been covered by a protective coating 320 i.e., after having applied step 235 of FIG. 2.

FIG. 3f illustrates the configuration of PWB 300 after laser drilling of holes into the added dielectric layer. These holes will generate metal connections with the underlying metal tracks (310) on layer (304). When seeding layers 322 and 324 with colloidal alloy of copper and palladium are applied on the whole surfaces of the board as described by reference to step 240 of FIG. 2.

FIG. 3g illustrates the step of masking PWB 300 with photoresist material (step 245 of FIG. 2) in order to build conductive tracks on the board surfaces. This is according to the technology that “Add” layers to the core, in this case the definition of the copper tracks is by additive plate (addition of metal where needed to create the track). To that end, photoresist material layers 326 and 328 are applied on the whole surfaces of the board and then, the photoresist material is exposed and developed so as to be removed where conductive tracks must be formed e.g., in 330.

FIG. 3h depicts the state of PWB 300 after having plated conductive tracks 332 and 334 on its surfaces according to the applied mask, as described by reference to step 250 of FIG. 2.

FIG. 3i depicts the state of PWB 300 after having stripped the plating masks 326 and 328 and applied soft gold on the wire bond pads using an electro-less process. As mentioned above, a standard solution consists in plating a nickel layer on the pads and then a gold layer on the wire bond pads after having “flash-etched” the copper seeding. The soft gold plated pads are referred to as 336 and 338 on the drawing. FIG. 3i illustrates the state of the board after having applied steps 255 and 260 of FIG. 2.

FIG. 3j illustrates the step of stripping the protective coating 320 applied on sliding contact tabs 318 (step 265 of FIG. 2).

Finally, FIG. 3k illustrates the configuration of PWB 300 at the end of the process when the surfaces of the board have been recovered by a protective material. To that end, photoresist material layers 340 and 342 are applied on the whole surfaces of the board. Photoresist material layers 340 and 342 are then exposed and developed so as to remove the photoresist material from the sliding contact tabs 318 and the wire bond pads wherein electronic components should be soldered. FIG. 3k illustrates the state of the board after having applied step 270 of FIG. 2.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of plating a printed wiring board (PWB), the method comprising:
applying a first plated metal layer having a first hardness in a first region of the PWB;
forming a protective coating on the first metal layer; and
applying a second plated metal layer having a second hardness in a second region of the PWB.

2. The method according to claim 1 further comprising removing the protective coating.

3. The method according to claim 1, wherein the first hardness is greater than the second hardness.

4. The method according to claim 1, wherein the first plated metal layer is applied using an electro-plating process.

5. The method according to claim 1, wherein the first plated metal layer is applied using an electro-less plating process.

6. The method according to claim 1, wherein the second plated metal layer is applied using an electro-less plating process.

7. The method according to claim 1, wherein the first plated metal layer is applied to a plurality of conductive tabs forming an edge connector on the PWB.

8. The method according to claim 1, wherein the second plated metal layer is applied to a plurality of conductive pads adapted for connecting a surface mount component or an integrated circuit chip package to the PWB.

9. The method according to claim 1, wherein the first plated metal layer comprises a composite layer of nickel followed by a layer of gold-cobalt alloy.

10. The method according to claim 8, wherein the second plated metal layer is formed after flash-etching the conductive pads and comprises a composite layer of nickel followed by a layer of gold.

11. A method for manufacturing a Printed Wire Board (PWB) from a core having at least one external conductive layer, said method comprising the steps of,
etching said at least one external conductive layer to form at least one sliding contact tab;
applying a dielectric material on said at least one external conductive layer;
removing partially said dielectric material from said at least one sliding contact tab;
electroplating said at least one sliding contact tab;
applying a protective coating on said at least one sliding contact tab;
applying colloidal seeding material on said dielectric material;
plating partially said colloidal seeding material using an additive process; and
removing said protective coating from said at least one sliding contact tab.

12. The method according to claim 1 wherein said steps of applying a dielectric material, applying colloidal seeding material on said dielectric material and plating partially said colloidal seeding material using an additive process are repeated so as to create a plurality of conductive planes.

13. The method according to claim 1 further comprising the step of applying bondable material using an electro-less process to form at least one soldering pad.

14. The method according to claim 1 further comprising the following steps:
applying a temporary mask;
plating soft gold on said at least one soldering pad; and
removing said temporary mask.

15. The method according to claim 13, wherein said step of applying bondable material using an electro-less process comprises applying a gold layer.

16. The method according to claim 5 wherein said step of applying bondable material using an electro-less process further comprises applying a nickel layer before applying said gold layer.

17. The method according to claim 1, wherein said step of electroplating said at least one sliding contact tab comprises:
electroplating nickel; and
electroplating an alloy of gold and cobalt.

18. The method according to claim 1, wherein said core is a reinforced glass core.

19. The method according to claim 1, wherein said at least one external conductive layer is made of copper.

20. The method according to claim 1, wherein said colloidal seeding material comprises copper and palladium, said additive process comprising the step of plating copper.

21. The method according to claim 16 wherein said bondable material comprises nickel and gold.
